(19) United States
(12) Patent Application Publication
(10) Pub. No.: US 2026/0005055 A1
(43) Pub. Date: Jan. 1, 2026

(54) SUBSTRATE ALIGNMENT APPARATUS, SUBSTRATE BONDING APPARATUS INCLUDING THE SAME, AND SUBSTRATE BONDING METHOD USING THE SUBSTRATE BONDING APPARATUS

(71) Applicant: Samsung Electronics Co., Ltd., Suwon-si (KR)

(72) Inventors: Jae Ho HONG, Suwon-si (KR); Tae Hong MIN, Suwon-si (KR); Sang Jun PARK, Suwon-si (KR); Tae-Hoi PARK, Suwon-si (KR); Sang-Ho YUN, Suwon-si (KR)

(21) Appl. No.: 19/210,001

(22) Filed: May 16, 2025

(30) Foreign Application Priority Data
Jul. 1, 2024 (KR) 10-2024-0086327

(51) Int. Cl. H01L 21/68; H01L 23/00

(52) U.S. Cl. CPC H01L 21/681; H01L 24/74; H01L 2224/74

(57) ABSTRACT

A substrate alignment apparatus is provided which includes a first support including first and second side surfaces opposite each other, wherein a first substrate on which a first alignment mark has been formed is placed on the first support; a second support disposed on the first support and including third and fourth side surfaces opposite each other, wherein a second substrate on which a second alignment mark has been formed is placed on the second support; a first recognition module disposed on the first side surface and configured to recognize the second alignment mark using diffracted light reflected from the second alignment mark; and a second recognition module disposed on the fourth side surface positioned above the second side surface and configured to recognize the first alignment mark using diffracted light reflected from the first alignment mark.

### CROSS-REFERENCE TO RELATED APPLICATION

This application claims priority under 35 U.S.C. § 119 from Korean Patent Application No. 10-2024-0086327, filed on Jul. 1, 2024, in the Korean Intellectual Property Office, and all the benefits accruing therefrom under 35 U.S.C. § 119, the contents of which in its entirety are herein incorporated by reference.

### BACKGROUND

### Field

The present disclosure relates to a substrate alignment apparatus, a substrate bonding apparatus including the same, and a substrate bonding method using the substrate bonding apparatus.

### Description of Related Art

In a semiconductor device with a three-dimensional connection structure, reliable bonding of two semiconductor wafers to each other is required. When the two semiconductor wafers are precisely bonded to each other, a semiconductor device with better performance and a smaller size may be manufactured.

Various schemes for bonding the two semiconductor wafers to each other are being developed. However, there is a need to improve a precision of a wafer bonding process.

### SUMMARY

A technical purpose of the present disclosure is to provide a substrate alignment apparatus that may precisely recognize an alignment mark.

Another technical purpose of the present disclosure is to provide a substrate bonding apparatus that may reliably bond substrates to each other.

Still another technical purpose of the present disclosure is to provide a substrate bonding method that may reliably bond substrates to each other.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A substrate alignment apparatus according to some embodiments of the present disclosure in order to achieve the above purpose includes a first support including first and second side surfaces opposite each other, wherein a first substrate on which a first alignment mark has been formed is placed on the first support; a second support disposed on the first support and including third and fourth side surfaces opposite each other, wherein a second substrate on which a second alignment mark has been formed is placed on the second support; a first recognition module disposed on the first side surface and configured to recognize the second alignment mark using diffracted light reflected from the second alignment mark; and a second recognition module disposed on the fourth side surface positioned above the second side surface and configured to recognize the first alignment mark using diffracted light reflected from the first alignment mark.

A substrate bonding apparatus according to some embodiments of the present disclosure in order to achieve the above purpose includes a first support including first and second side surfaces opposite each other in a horizontal direction and an upper surface connecting the first and second side surfaces to each other, wherein a first substrate on which a first diffraction grating has been formed is disposed on the first support; a second support including third and fourth side surfaces opposite each other in the horizontal direction, and a lower surface connecting the third and fourth side surfaces to each other and facing the upper surface in a vertical direction, wherein a second substrate on which a second diffraction grating has been formed is disposed on the second support; a first recognition module disposed on the first side surface and configured to generate light to be incident on the second diffraction grating, and to recognize the second diffraction grating using a first pattern generated via interference of light reflected from the second diffraction grating; and a second recognition module disposed on the fourth side surface positioned above the second side surface, and configured to generate light to be incident on the first diffraction grating, and to recognize the first diffraction grating using a second pattern generated via interference of light reflected from the first diffraction grating.

A substrate bonding method according to some embodiments of the present disclosure in order to achieve the above purpose includes placing a first substrate having a first alignment mark formed thereon on a first support, wherein the first support includes first and second side surfaces opposite each other in a horizontal direction; placing a second substrate having a second alignment mark formed thereon on a second support, wherein the second support includes first and second side surfaces opposite each other in the horizontal direction; recognizing, by a first diffraction-based recognition module disposed on the first side surface of the first support, the second alignment mark of the second substrate; and recognizing, by a second diffraction-based recognition module disposed on the second side surface of the second support, the first alignment mark of the first substrate.

Specific details of other embodiments are included in the detailed descriptions and drawings.

### BRIEF DESCRIPTION OF DRAWINGS

The above and other aspects and features of the present disclosure will become more apparent by describing in detail illustrative embodiments thereof with reference to the attached drawings, in which:

FIG. 1 is a plan view showing an upper surface of a substrate used in a substrate alignment apparatus according to some example embodiments;

FIG. 2 to FIG. 5 are diagrams for illustrating a configuration in which a recognition module recognizes an alignment mark of a substrate according to some example embodiments.

FIG. 6 to FIG. 9 are diagrams for illustrating formation of a Moire pattern by a substrate alignment apparatus according to some example embodiments;

FIG. 10 is a diagram for illustrating zero point adjustment of a recognition module according to some example embodiments;

FIG. 11 is a diagram for illustrating a configuration in which substrate bonding is performed using a substrate alignment apparatus according to some example embodiments; and

FIG. 12 is a flowchart for illustrating a substrate bonding method according to some example embodiments.

### DETAILED DESCRIPTIONS

Hereinafter, embodiments will be described in detail with reference to the accompanying drawings. Like reference characters refer to like elements throughout.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention.

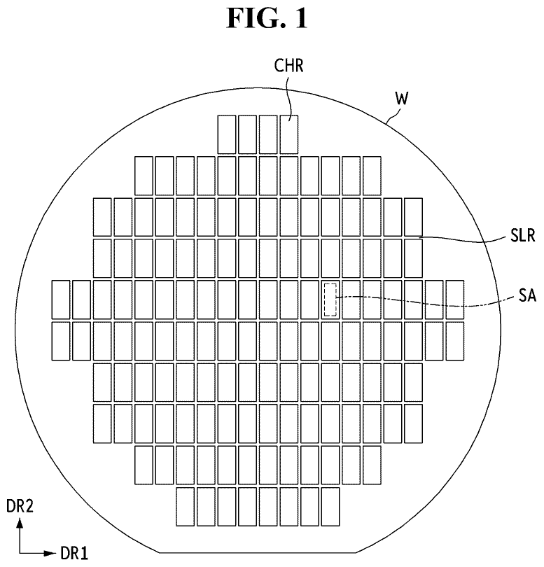

FIG. 1 is a plan view showing an upper surface of a substrate used in a substrate alignment apparatus according to some example embodiments.

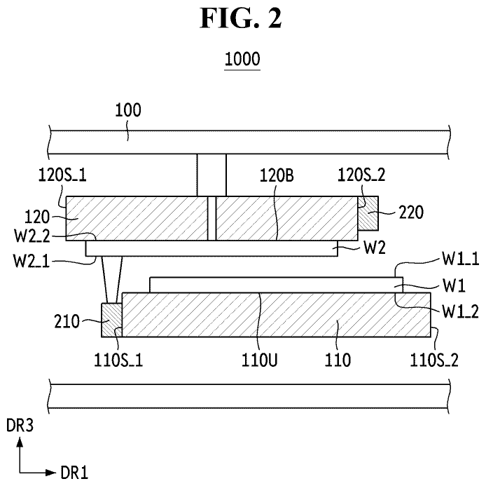

Referring to FIG. 1, a substrate W may include a plurality of chip areas CHR and scribe line areas SLR disposed between the chip areas CHR and extending in a line. In some embodiments, the substrate W of FIG. 1 may refer to at least one of first and second substrates W1 and W2 of FIG. 2 to FIG. 5, which will be described later.

The chip areas CHR may be disposed on the upper surface of the substrate W and may be arranged along a first direction X and a second direction Y perpendicular to the first direction X. Each chip area CHR may be surrounded with the scribe line areas SLR.

The semiconductor memory device such as Dynamic Random Access Memory (DRAM), Static Random Access Memory (SRAM), NAND Flash Memory, and Resistive Random Access Memory (RRAM) may be provided on the chip areas CHR. Alternatively, a Micro Electro Mechanical Systems (MEMS) device, an optoelectronic device, or a processor such as a CPU or a DSP may be provided on the chip areas CHR. Alternatively, standard cells including semiconductor elements such as OR gates or AND gates may be provided on the chip areas CHR. Redistribution chip pads for inputting and outputting data or signals to semiconductor integrated circuits and redistribution pads for inputting and outputting signals to test circuits may be connected to each chip area CHR.

The scribe line areas SLR may include a scribe line area SLR extending in the first direction DR1 and disposed between the chip areas CHR and a scribe line area SLR extending in the second direction DR2 and disposed between the chip areas CHR. For example, a plurality of scribe line areas SLR may extend lengthwise in the first direction DR1 and be disposed between chip areas CHR adjacent in the second direction DR2, and a plurality of scribe line areas SLR may extend lengthwise in the second direction DR2 and be disposed between chip areas CHR adjacent in the first direction DR1. The plurality of scribe line areas SLR extending lengthwise in the first direction DR1 may intersect the plurality of scribe line areas SLR extending lengthwise in the second direction DR2. Although not specifically shown, the scribe line area SLR may include a cutting area cut by a sawing or cutting machine and edge areas between the cutting area and the chip areas CHR.

The substrate W may include a plurality of shot areas SA. Each shot area SA may have a rectangular shape. However, embodiments of the present disclosure are not limited thereto. The shot area SA may be an entire area of a lithography mask that may be transferred to the substrate W (or photoresist formed on the substrate) through one exposure. A semiconductor device may be generated via transferring circuit patterns respectively formed on different masks to the shot area SA in an overlapping manner.

The number and a size of chip areas CHR included in one shot area SA may vary depending on a type and a specification of an element to be formed therein. For example, the shot area SA may include only one chip area.

Each of first and second alignment marks AK1 an AK2 as described later may be formed within at least one shot area SA.

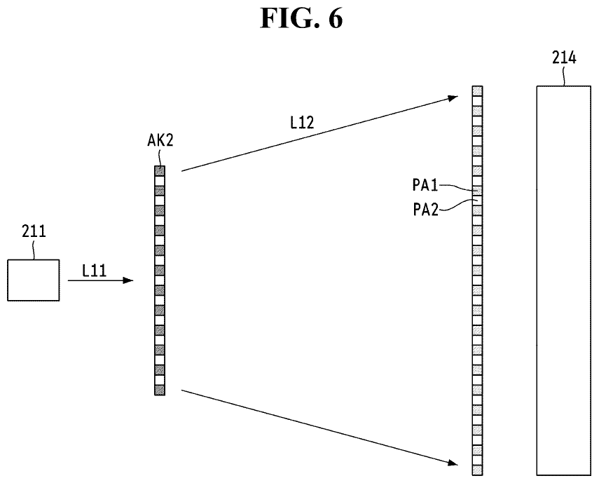

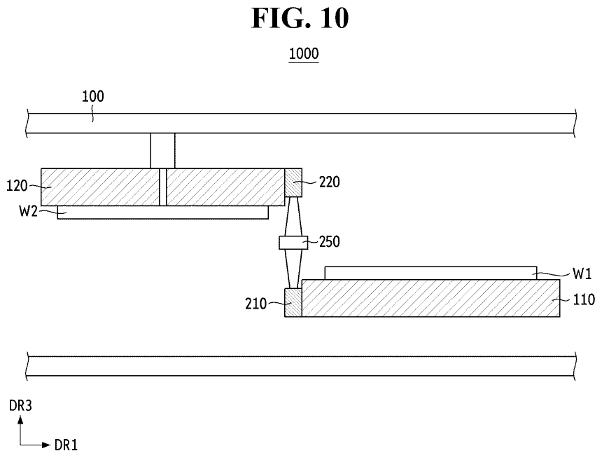

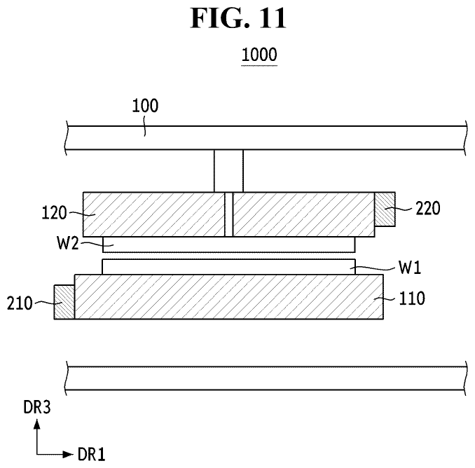

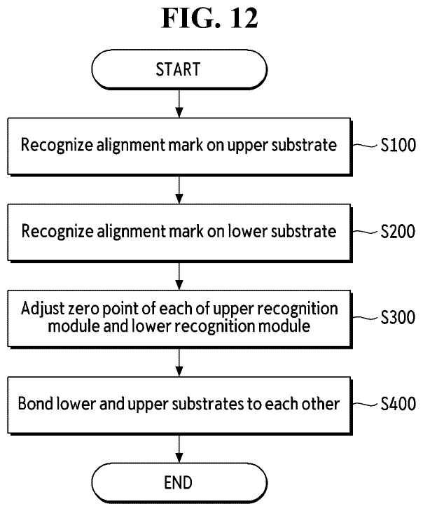

FIG. 2 to FIG. 5 are diagrams for illustrating a configuration in which a recognition module recognizes an alignment mark of a substrate according to some example embodiments. FIG. 6 to FIG. 9 are diagrams for illustrating formation of a Moire pattern by a substrate alignment apparatus according to some example embodiments. FIG. 10 is a diagram for illustrating zero point adjustment of a recognition module according to some example embodiments. FIG. 11 is a diagram for illustrating a configuration in which substrate bonding is performed using a substrate alignment apparatus according to some example embodiments. FIG. 12 is a flowchart for illustrating a substrate bonding method according to some example embodiments.

Hereinafter, a substrate alignment apparatus according to some embodiments will be described.

Referring to FIG. 2 to FIG. 5, a substrate alignment apparatus 1000 according to some embodiments may include a chamber 100, a first support 110, a second support 120, a first recognition module 210, and a second recognition module 220.

In an inner space of the chamber 100, the first substrate W1, the second substrate W2, the first support 110, the second support 120, the first recognition module 210, and the second recognition module 220 may be disposed. The chamber 100 may have an inner space defined therein in which a substrate bonding process using the substrate alignment apparatus 1000 according to some embodiments is performed.

The first substrate W1 may include a first surface W1_1 and a second surface W1_2 facing away from each other. For example, the first surface W1_1 and the second surface W1_2 may be opposite to one another. The first surface W1_1 of the first substrate W1 may extend in a first direction DR1 and a second direction DR2 that perpendicularly intersect each other. A third direction DR3 may be a height direction perpendicular to each of the first direction DR1 and the second direction DR2. For example, the third direction DR3 may correspond to a height or distance between the first surface W1_1 and the second surface W1_2 of the first substrate W1. In some embodiments, the first direction DR1 and the second direction DR2 may mean a first horizontal direction and a second horizontal direction, respectively, and the third direction DR3 may mean a vertical direction.

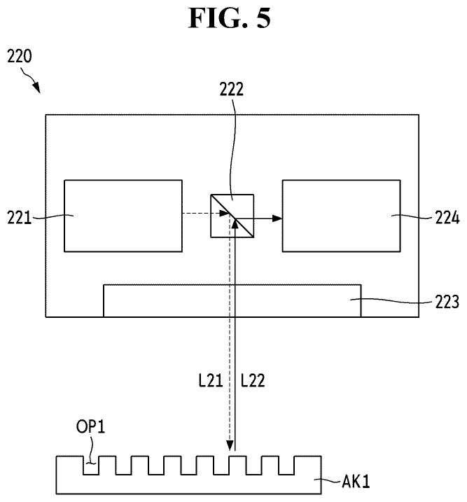

The first alignment mark (e.g., first alignment mark AK1 in FIG. 5), which will be described later, may be formed on the first surface W1_1 of the first substrate W1. A first opening OP1 may be formed in the first alignment mark (e.g., first alignment mark AK1 in FIG. 5). In some embodiments, the first alignment mark (e.g., first alignment mark AK1 in FIG. 5) may be referred to as a first diffraction grating.

The first support 110 may include first and second side surfaces 110S_1 and 110S_2 facing away from each other in the first direction DR1, and an upper surface 110U connecting the first and second side surfaces 110S_1 and 110S_2 to each other. For example, the first and second side surfaces 110S_1 and 110S_2 may be opposite to one another, and the upper surface 110U may be perpendicular to both the first and second side surfaces 110S_1 and 110S_2. The first substrate W1 may be disposed on the upper surface 110U of the first support 110.

The second substrate W2 may include a third surface W2_1 and a fourth surface W2_2 facing away from each other. For example, the third surface W2_1 and the fourth surface W2_2 may be opposite to one another. The third surface W2_1 of the second substrate W2 may extend in each of the first direction DR1 and the second direction DR2.

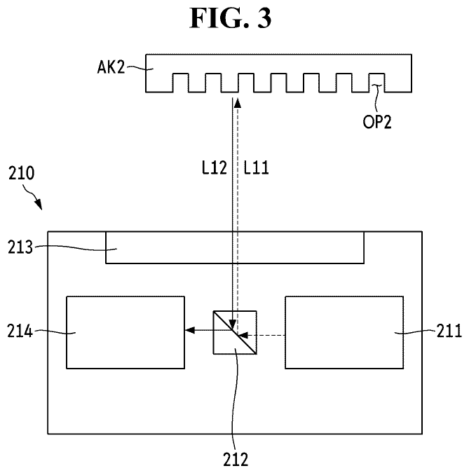

The second alignment mark (e.g., second alignment mark AK2 in FIG. 3), which will be described later, may be formed on the third surface W2_1 of the second substrate W2. A second opening OP2 may be formed in the second alignment mark (e.g., second alignment mark AK2 in FIG. 3). In some embodiments, the second alignment mark (e.g., second alignment mark AK2 in FIG. 3) may be referred to as a second diffraction grating.

The second support 120 may include third and fourth side surfaces 120S_1 and 120S_2 facing away from each other in the first horizontal direction DR1, and a lower surface 120B connecting the third and fourth side surfaces 120S_1 and 120S_2 to each other, and facing the upper surface 110U of the first support 110 in the third direction DR3. For example, the third and fourth side surfaces 120S_1 and 120S_2 may be opposite to one another, and the lower surface 120B may be perpendicular to both the third and fourth side surfaces 120S_1 and 120S_2. The second substrate W2 may be disposed on the lower surface 120B of the second support 120.

The first recognition module 210 may be disposed on the first side surface 110S_1 of the first support 110.

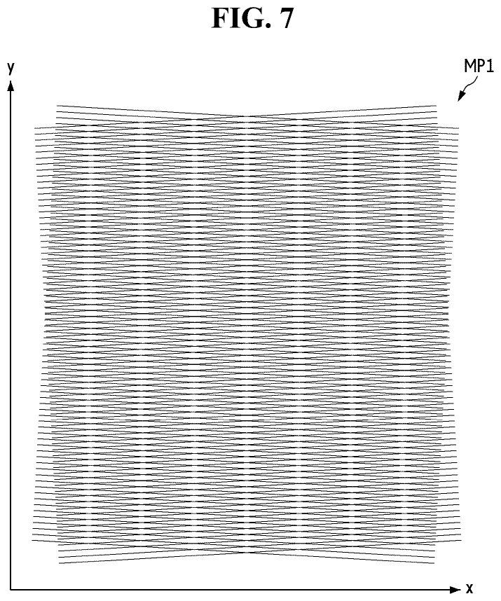

The first recognition module 210 may recognize the second alignment mark AK2 using diffracted light reflected from the second alignment mark AK2. The first recognition module 210 may generate light to be incident on the second alignment mark AK2, and recognize the second alignment mark AK2 using a first Moire pattern (e.g., first Moire pattern MP1 in FIG. 7) generated via interference of light reflected from the second alignment mark AK2.

In some embodiments, the first recognition module 210 may be referred to as a first diffraction-based recognition module.

Referring to FIG. 3, the first recognition module 210 may include a first light source 211, a first beam splitter 212, a first optical system 213, and a first detector 214.

The first light source 211 may generate light L11 incident on the second alignment mark AK2. The first light source 211 may be, for example, a laser light source. However, embodiments of the present disclosure are not limited thereto.

The first beam splitter 212 may be disposed between the first light source 211 and the first detector 214. The first beam splitter 212 may split light generated from the first light source 211.

The first optical system 213 may condense light generated from the first light source 211 so that the condensed light may be stably emitted. The first optical system 213 may be, for example, a condensing lens. However, embodiments of the present disclosure are not limited thereto.

The first detector 214 may receive diffracted light L12 reflected from the second alignment mark AK2.

The second recognition module 220 may be disposed on the fourth side surface 120S_2 of the second support 120. The second recognition module 220 may be disposed above second side surface 110S_2 of the first support 110. In some embodiments, as the first support 110 is movable in the first direction DR1, the first side surface 110S_1 and the third side surface 120S_1 may not be exactly aligned with each other in the third direction DR3, and the second side surface 110S_2 and the fourth side surface 120S_2 may not be exactly aligned with each other in the third direction DR3.

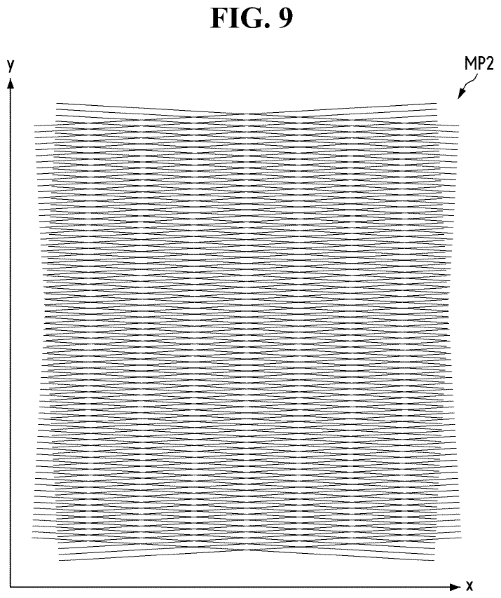

The second recognition module 220 may recognize the first alignment mark AK1 using the diffracted light reflected from the first alignment mark AK1. The second recognition module 220 may generate light to be incident on the first alignment mark AK1, and may recognize the first alignment mark AK1 using a second Moire pattern (e.g., second Moire pattern MP2 in FIG. 9) generated via interference of light reflected from the first alignment mark AK1.

In some embodiments, the second recognition module 220 may be referred to as a second diffraction-based recognition module 220.

Referring to FIG. 5, the second recognition module 220 may include a second light source 221, a second beam splitter 222, a second optical system 223, and a second detector 224.

The second light source 221 may generate light L21 incident on the first alignment mark AK1. The second light source 221 may be, for example, a laser light source. However, embodiments of the present disclosure are not limited thereto.

The second beam splitter 222 may be disposed between the second light source 221 and the second detector 224. The second beam splitter 222 may split the light generated from the second light source 221.

The second optical system 223 may condense light generated from the second light source 221 so that the condensed light may be stably emitted. The second optical system 223 may be, for example, a condensing lens. However, embodiments of the present disclosure are not limited thereto.

The second detector 224 may receive the diffracted light L22 reflected from the first alignment mark AK1.

Referring to FIG. 6 and FIG. 7, the first light source 211 may generate light L11 incident on the second alignment mark AK2. A first signal PA1 may be generated via constructive interference of the diffracted light L12 reflected from the second alignment mark AK2 and received by the first detector 214. A second signal PA2 may be generated via destructive interference of the diffracted light L12 reflected from the second alignment mark AK2 and received by the first detector 214.

The first recognition module 210 may recognize a shape of the second alignment mark AK2 using a difference between intensities of the first and second signals PA1 and PA2. That is, the first recognition module 210 may recognize the shape of the second alignment mark AK2 based on the difference in the light intensity due to different interferences of light reflected from the second alignment mark AK2.

The first Moire pattern MP1 may be formed via constructive interference and destructive interference of light reflected from the second alignment mark AK2. The first recognition module 210 may recognize the second alignment mark AK2 using the first Moire pattern MP1 generated via overlapping of the diffracted light L12 reflected from the second alignment mark AK2.

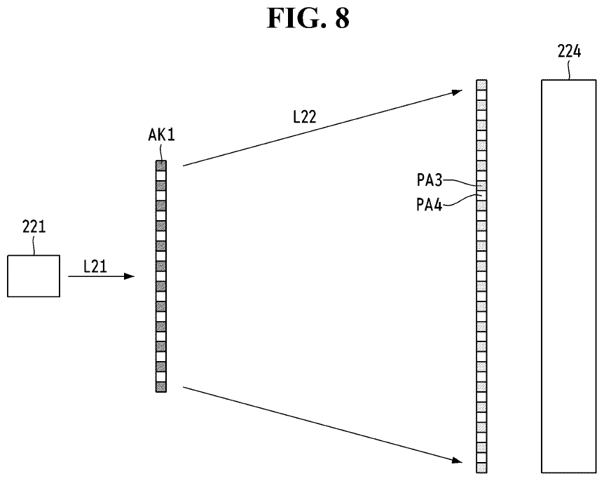

Referring to FIG. 8 and FIG. 9, the second light source 221 may generate light L21 incident on the first alignment mark AK1. A third signal PA3 may be generated via constructive interference of the diffracted light L22 reflected from the first alignment mark AK1 and received by the second detector 224, and a fourth signal PA4 may be generated via destructive interference of the diffracted light L22 reflected from the first alignment mark AK1 and received by the second detector 224.

The second recognition module 220 may recognize the shape of the first alignment mark AK1 using a difference between intensities of the third and fourth signals PA3 and PA4. That is, the second recognition module 220 may recognize the shape of the first alignment mark AK1 based on the difference in the light intensity due to different interferences of the light reflected from the first alignment mark AK1.

The second Moire pattern MP2 may be formed via constructive interference and destructive interference of light reflected from the first alignment mark AK1. The second recognition module 220 may recognize the first alignment mark AK1 using the second Moire pattern MP2 generated via overlapping of the diffracted light L22 reflected from the first alignment mark AK1.

In one example, a shape of each of the first and second Moire patterns MP1 and MP2 as shown in FIG. 7 and FIG. 9 is merely an example, and the shape of the Moire pattern formed according to some embodiments is not limited thereto.

As the first and second Moire patterns MP1 and MP2 are formed, a difference between contrasts of the interference patterns may become clearer. The substrate alignment apparatus according to some embodiments may use the diffraction-based recognition module capable of recognizing the Moire pattern, and thus may recognize more precisely a finer alignment mark. Accordingly, reliability of each of a substrate alignment process and a substrate bonding process may be improved.

Hereinafter, a substrate bonding apparatus including a substrate alignment apparatus and a substrate bonding method using the substrate bonding apparatus according to some example embodiments will be described.

The substrate bonding apparatus according to some embodiments may include the substrate alignment apparatus 1000 described above using FIG. 2 to FIG. 9 and a controller (not shown). After the first and second recognition modules 210 and 220 recognize the second and first alignment marks AK2 and AK1, respectively, the alignment and bonding processes may be performed on the first and second substrates W1 and W2 by the controller (not shown).

First, the first and second substrates W1 and W2 on which the first and second alignment marks AK1 and AK2 have been formed, respectively, may be provided on the first and second supports 110 and 120, respectively. Each of the first and second supports 110 and 120 may include first and second side surfaces facing away from each other in the first direction DR1. In this regard, the first side surface may correspond to each of the first side surface 110S_1 and the third side surface 120S_1, and the second side surface may correspond to each of the second side surface 110S_2 and the fourth side surface 120S_2.

Thereafter, referring to FIG. 2, FIG. 3, and FIG. 12 together, the first recognition module 210 disposed on the first side surface 110S_1 of the first support 110 may recognize the second alignment mark AK2 of the second substrate W2 in S100. The second substrate W2 may be referred to as the upper substrate.

At this time, in the third direction DR3, the first substrate W1 may not entirely overlap the second substrate W2. For example, the first substrate W1 may partially overlap the second substrate W2.

The first recognition module 210 may generate the light incident on the second alignment mark AK2, and may recognize the shape of the second alignment mark AK2 using the first Moire pattern (e.g., first Moire pattern MP1 in FIG. 7) generated via interference of light reflected from the second alignment mark AK2.

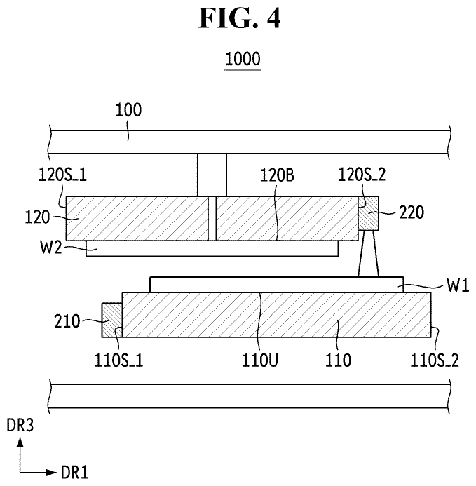

Thereafter, referring to FIG. 4, FIG. 5, and FIG. 12 together, the second recognition module 220 disposed on the fourth side surface 120S_2 of the second support 120 may recognize the first alignment mark AK1 of the first substrate W1 in S200. The first substrate W1 may be referred to as the lower substrate.

At this time, in the third direction DR3, the first substrate W1 may not entirely overlap the second substrate W2.

The second recognition module 220 may generate the light incident on the first alignment mark AK1, and may recognize the shape of the first alignment mark AK1 using the second Moire pattern (e.g., second Moire pattern MP2 in FIG. 9) generated via interference of light reflected from the first alignment mark AK1.

Thereafter, referring to FIG. 10 and FIG. 12 together, zero point adjustment of each of the first and second recognition modules 210 and 220 may be performed in S300. The first and second recognition modules 210 and 220 may be referred to as the lower and upper recognition modules, respectively. The first support 110 may be movable in a direction parallel to the first direction DR1 so that the first and second recognition modules 210 and 220, and a target object 250 are aligned with each other in the third direction Z. Accordingly, horizontal position adjustment of each of the first and second recognition modules 210 and 220 may be performed.

In some embodiments, it is shown that the zero point adjustment of each of the first and second recognition modules 210 and 220 is performed after the first and second recognition modules 210 and 220 respectively recognize the second and first alignment marks AK2 and AK1. However, embodiments of the present disclosure are not limited thereto. That is, the zero point adjustment of each of the first and second recognition modules 210 and 220 may be performed before the first and second recognition modules 210 and 220 respectively recognize the second and first alignment marks AK2 and AK1.

Thereafter, referring to FIG. 11 and FIG. 12 together, the first and second substrates W1 and W2 may be aligned with each other in the third direction DR3 and may be bonded to each other in S400. The first and second substrates W1 and W2 may be aligned with each other by the controller (not shown), based on the recognized first and second alignment marks AK1 and AK2. Afterwards, a bonding process may be performed on the first and second substrates W1 and W2 by the controller (not shown). The first and second substrates W1 and W2 may be referred to as the lower and upper substrates, respectively.

The controller (not shown) may be embodied as hardware, firmware, software, or any combination thereof. For example, the controller (not shown) may be a computing device such as a workstation computer, a desktop computer, a laptop computer, or a tablet computer. Furthermore, the controller (not shown) may include storage (e.g., memory) in which a program for aligning and bonding the substrates with and to each other may be stored. The program may be recorded in a storage medium readable by a computer or the like.

For example, the controller (not shown) may include a memory device such as ROM (Read Only Memory) and RAM (Random Access Memory), and a processor configured to perform predetermined operations and algorithms, such as a microprocessor and CPU (Central Processing Unit), GPU (Graphics Processing Unit), etc. Furthermore, the controller (not shown) may include a receiver and a transmitter for receiving and transmitting electrical signals.

Although the embodiments of the present disclosure have been described above with reference to the accompanying drawings, the present disclosure may not be limited to the embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that the embodiments as described above are not restrictive but illustrative in all respects.

What is claimed is:

1. A substrate alignment apparatus comprising:
a first support including first and second side surfaces opposite each other, wherein a first substrate on which a first alignment mark has been formed is placed on the first support;
a second support disposed on the first support and including third and fourth side surfaces opposite each other, wherein a second substrate on which a second alignment mark has been formed is placed on the second support;
a first recognition module disposed on the first side surface and configured to recognize the second alignment mark using diffracted light reflected from the second alignment mark; and
a second recognition module disposed on the fourth side surface positioned above the second side surface and configured to recognize the first alignment mark using diffracted light reflected from the first alignment mark.

2. The substrate alignment apparatus of claim 1, wherein the first recognition module is configured to recognize the second alignment mark using a first Moire pattern generated via overlapping of the diffracted light reflected from the second alignment mark.

3. The substrate alignment apparatus of claim 1,
wherein a first signal and a second signal are respectively generated via different interferences of the diffracted light reflected from the second alignment mark, and
wherein the first recognition module is configured to recognize a shape of the second alignment mark using a difference between intensities of the first and second signals.

4. The substrate alignment apparatus of claim 1, wherein the second recognition module is configured to recognize the first alignment mark using a second Moire pattern generated via overlapping of diffracted light reflected from the first alignment mark.

5. The substrate alignment apparatus of claim 1,
wherein a third signal and a fourth signal are respectively generated via different interferences of diffracted light reflected from the first alignment mark, and
wherein the second recognition module is configured to recognize a shape of the first alignment mark using a difference between intensities of the third and fourth signals.

6. The substrate alignment apparatus of claim 1,
wherein the first recognition module includes:
a first light source for generating light to be incident on the second alignment mark; and
a first detector for receiving the diffracted light reflected from the second alignment mark, and
wherein the second recognition module includes:
a second light source for generating light to be incident on the first alignment mark, and
a second detector for receiving the diffracted light reflected from the first alignment mark.

7. The substrate alignment apparatus of claim 6,
wherein the first recognition module further includes a first beam splitter disposed between the first light source and the first detector and configured to split the light generated from the first light source, and
wherein the second recognition module further includes a second beam splitter disposed between the second light source and the second detector and configured to split the light generated from the second light source.

8. The substrate alignment apparatus of claim 6,
wherein the first recognition module further includes a first optical system for condensing the light generated from the first light source, and
wherein the second recognition module further includes a second optical system for condensing the light generated from the second light source.

9. The substrate alignment apparatus of claim 8, wherein each of the first and second optical systems includes a condensing lens.

10. A substrate bonding apparatus comprising:
a first support including first and second side surfaces opposite each other in a horizontal direction and an upper surface connecting the first and second side surfaces to each other, wherein a first substrate on which a first diffraction grating has been formed is disposed on the first support;
a second support including third and fourth side surfaces opposite each other in the horizontal direction, and a lower surface connecting the third and fourth side surfaces to each other and facing the upper surface in a vertical direction, wherein a second substrate on which a second diffraction grating has been formed is disposed on the second support;
a first recognition module disposed on the first side surface and configured to generate light to be incident on the second diffraction grating, and to recognize the second diffraction grating using a first pattern generated via interference of light reflected from the second diffraction grating; and
a second recognition module disposed on the fourth side surface positioned above the second side surface, and configured to generate light to be incident on the first diffraction grating, and to recognize the first diffraction grating using a second pattern generated via interference of light reflected from the first diffraction grating.

11. The substrate bonding apparatus of claim 10,
wherein the first pattern is generated via constructive interference and destructive interference of the light reflected from the second diffraction grating, and
wherein the second pattern is generated via constructive interference and destructive interference of the light reflected from the first diffraction grating.

12. The substrate bonding apparatus of claim 10,
wherein the first recognition module is configured to recognize a shape of the second diffraction grating based on a difference between signal intensities respectively resulting from different interferences of the light reflected from the second diffraction grating, and
wherein the second recognition module is configured to recognize a shape of the first diffraction grating based on a difference between signal intensities respectively resulting from different interferences of the light reflected from the first diffraction grating.

13. The substrate bonding apparatus of claim 10, further comprising a controller configured to bond the first and second substrates to each other, based on the recognized shape of each of the first and second diffraction gratings.

14. The substrate bonding apparatus of claim 10,
wherein the first recognition module includes:
a first light source for generating light to be incident on the second diffraction grating;
a first detector for receiving light reflected from the second diffraction grating; and
a first beam splitter disposed between the first light source and the first detector, and configured to split the light generated from the first light source, and
wherein the second recognition module includes:
a second light source for generating light to be incident on the first diffraction grating;
a second detector for receiving the light reflected from the first diffraction grating; and
a second beam splitter disposed between the second light source and the second detector, and configured to split the light generated from the second light source.

15. The substrate bonding apparatus of claim 14,
wherein the first recognition module further includes a first condensing lens for condensing the light generated from the first light source, and
wherein the second recognition module further includes a second condensing lens for condensing the light generated from the second light source.

16. A substrate bonding method comprising:
placing a first substrate having a first alignment mark formed thereon on a first support, wherein the first support includes first and second side surfaces opposite each other in a horizontal direction;
placing a second substrate having a second alignment mark formed thereon on a second support, wherein the second support includes first and second side surfaces opposite each other in the horizontal direction;
recognizing, by a first diffraction-based recognition module disposed on the first side surface of the first support, the second alignment mark of the second substrate; and
recognizing, by a second diffraction-based recognition module disposed on the second side surface of the second support, the first alignment mark of the first substrate.

17. The substrate bonding method of claim 16,
wherein the recognizing, by the first diffraction-based recognition module disposed on the first side surface of the first support, the second alignment mark of the second substrate includes:
generating, by the first diffraction-based recognition module, the light to be incident on the second alignment mark; and
recognizing a shape of the second alignment mark using a first pattern generated via interference of light reflected from the second alignment mark, and
wherein the recognizing, by the second diffraction-based recognition module disposed on the second side surface of the second support, the first alignment mark of the first substrate includes:
generating, by the second diffraction-based recognition module light to be incident on the first alignment mark; and
recognizing, by the second diffraction-based recognition module, a shape of the first alignment mark using a second pattern generated via interference of light reflected from the first alignment mark.

18. The substrate bonding method of claim 16, wherein the first substrate does not entirely overlap the second substrate in a direction perpendicular to an upper surface of each of the first and second substrates.

19. The substrate bonding method of claim 16, further comprising adjusting a horizontal position of each of the first and second diffraction-based recognition modules.

20. The substrate bonding method of claim 16, further comprising:
aligning the first and second substrates with each other based on the recognized first and second alignment marks; and
bonding the first and second substrates to each other.
